(19) United States
(12) Patent Application Publication
(10) Pub. No.: US 2026/0165005 A1
(43) Pub. Date: Jun. 11, 2026

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xue ZHOU, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/706,374

(22) PCT Filed: Apr. 1, 2024
(86) PCT No.: PCT/CN2024/085186

§ 371 Date: Apr. 30, 2024

(30) Foreign Application Priority Data
Mar. 26, 2024 (CN) 202410353909.9

(51) Int. Cl. H10K 59/80

(52) U.S. Cl. CPC H10K 59/879; H10K 59/873

(57) ABSTRACT

The present application provides a display panel and a display device. The display panel includes a capping layer disposed between a light-emitting device layer and a thin film encapsulation layer. The capping layer includes a first capping layer, a second capping layer and a third capping layer. The second capping layer is disposed between the first capping layer and the third capping layer. The first capping layer is disposed adjacent to the light-emitting device layer. The third capping layer is disposed adjacent to the thin film encapsulation layer. A refractive index of the second capping layer is greater than a refractive index of the first capping layer and a refractive index of the third capping layer.

### TECHNICAL FIELD

The present application relates to the field of display technologies, and especially relates to a display panel and a display device.

### BACKGROUND

Due to Organic light-emitting diode (OLED) has advantages of autonomous light-emitting, wide operating temperature range, fast response speed, wide viewing angle, high luminous efficiency, being manufactured on flexible substrates, and low driving voltages and energy consumption, it has attracted attention of many display manufacturers around the world, and is known as the next generation display technology. At present, the market has increasingly higher power consumption requirements for organic light-emitting diode display panels.

Therefore, how to reduce power consumption of the organic light-emitting diode display panels is a technical problem that needs to be solved.

### SUMMARY

The present application provides a display panel and a display device to improve light extraction efficiency of the display panel and the display device, thereby helping to reduce power consumption of the display panel and the display device.

In a first aspect, the present application provides a display panel. The display panel includes a substrate, a light-emitting device layer, and a thin film encapsulation layer. The light-emitting device layer is disposed on a side of the substrate. The thin film encapsulation layer is disposed on a side of the light-emitting device layer facing away from the substrate. A capping layer is disposed between the light-emitting device layer and the thin film encapsulation layer. The capping layer includes a first capping layer, a second capping layer, and a third capping layer. The second capping layer is disposed between the first capping layer and the third capping layer. The first capping layer is disposed on a side of the second capping layer adjacent to the light-emitting device layer. The third capping layer is disposed on a side of the second capping layer adjacent to the thin film encapsulation layer. A refractive index of the second capping layer is greater than a refractive index of the first capping layer and a refractive index of the third capping layer.

In a second aspect, the present application provides a display device, the display device includes the above-mentioned display panel.

### BENEFICIAL EFFECTS

In the display panel and the display device of some embodiments of the present application, the capping layer disposed between the light-emitting device layer and the thin film encapsulation layer includes a first capping layer, a second capping layer, and a third capping layer. The second capping layer is disposed between the first capping layer and the third capping layer. The first capping layer is disposed on the side of the second capping layer adjacent to the light-emitting device layer. The third capping layer is disposed on the side of the second capping layer adjacent to the thin film encapsulation layer. The refractive index of the second capping layer is greater than the refractive index of the first capping layer and the refractive index of the third capping layer. Therefore, a plurality of capping layers are disposed on the light-emitting device layer, and refractive indexes of the plurality of capping layers maintain A combination of a low refractive index, a high refractive index, and a low refractive index. A combination design of the refractive indexes of the plurality of capping layers increase microcavity function outside the light-emitting device layer, so as to improve light extraction efficiency of lights emitted by the light-emitting device layer through the capping layer. In addition, the combination design of the refractive indexes of the plurality of capping layers further improve light loss caused by surface plasmon mode, so that part of the lights confined inside light-emitting devices are emitted outside the display panel, thereby further improving light extraction efficiency of the display panel, and helping reduce power consumption of the display panel.

### BRIEF DESCRIPTION OF THE DRAWINGS

FIG. 1 is a schematic cross-sectional structural diagram of a display panel according to some embodiments of the present application.

FIG. 2 is a partial enlarged schematic diagram of the display panel shown in FIG. 1.

FIG. 3 shows a blue light emission spectrum of a blue light-emitting unit of the display panel according to some embodiments of the present application and a blue light emission spectrum of a blue light emitting unit of a display panel of a comparative example.

FIG. 4 shows proportion of lights emitted by the display panel of some embodiments of the present application in four modes and proportion of lights emitted by the display panel of the comparative example in the four modes.

Reference numerals in drawings are marked as follows:
100, display panel;
11, substrate;
12, light-emitting device layer; 121, anode layer; 1211, first anode; 1212, second anode; 1213, third anode; 122, light-emitting layer; 1221, first light-emitting unit; 1222, second light-emitting unit; 1223, third light-emitting unit; 123, cathode layer;
13, capping layer; 131, first capping layer; 132, second capping layer; 133, third capping layer;
14, light-transmitting protective layer;
15, thin film encapsulation layer; 151, first inorganic encapsulation layer; 152, organic encapsulation layer; 153, second inorganic encapsulation layer;
161, driving circuit layer; 162, pixel definition layer; 162a, pixel opening.

### DETAILED DESCRIPTION OF THE EMBODIMENT

The technical solutions in the embodiments of the present application will be clearly and completely described below in conjunction with the drawings in the embodiments of the present application. Obviously, the embodiments described are only a part of the embodiments of the present application, rather than all the embodiments. Based on the embodiments in the present application, all other embodiments obtained by those skilled in the art without creative works should be deemed as falling with in the claims of the present application.

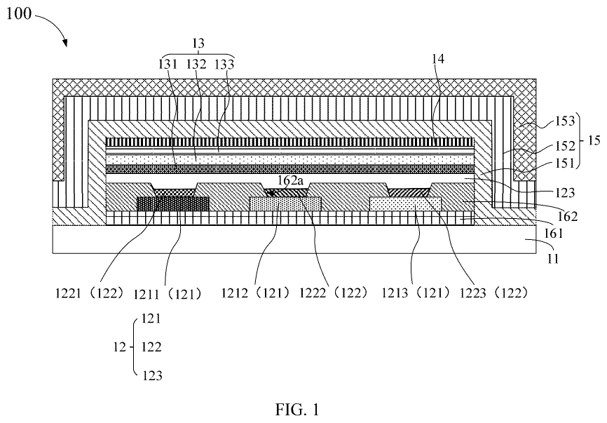

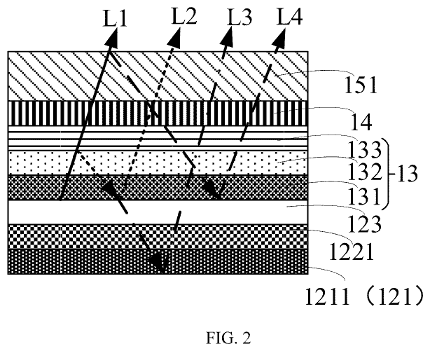

Please refer to FIGS. 1 and 2. FIG. 1 is a schematic cross-sectional structural diagram of a display panel according to some embodiments of the present application. FIG. 2 is a partial enlarged schematic diagram of the display panel shown in FIG. 1.

The display panel 100 includes a substrate 11, a light-emitting device layer 12, a thin film encapsulation layer 15, and a capping layer 13.

The substrate 11 may include a hard substrate, the hard substrate includes but is not limited to a glass substrate. The substrate 11 may also include a flexible substrate, the flexible substrate includes an organic layer. The organic layer includes but is not limited to a polyimide layer.

The light-emitting device layer 12 is disposed on a side of the substrate 11. The light-emitting device layer 12 includes an anode layer 121, a light-emitting layer 122, and a cathode layer 123. The light-emitting layer 122 is disposed between the anode layer 121 and the cathode layer 123.

The anode layer 121 is disposed on a side of the light-emitting layer 122 adjacent to the substrate 11. The anode layer 121 includes a first anode 1211, a second anode 1212, and a third anode 1213 that are spaced apart from each other. The anode layer 121 may include a first transparent conductive layer, a metal layer, and a second transparent conductive layer stacked in sequence. Therefore, each of the first anode 1211, the second anode 1212, and the third anode 1213 may include the first transparent conductive layer, the metal layer, and the second transparent conductive layer stacked in sequence. Metals have reflectivity, so that the first anode 1211, the second anode 1212, and the third anode 1213 can also reflect lights. The first transparent conductive layer and the second transparent conductive layer include at least one of indium tin oxide and indium zinc oxide. The metal layer includes silver.

The light-emitting layer 122 includes a first light-emitting unit 1221, a second light-emitting unit 1222, and a third light-emitting unit 1223 that are spaced apart from each other. The first light-emitting unit 1221, the second light-emitting unit 1222, and the third light-emitting unit 1223 emit lights different from each other. Any one of the first light-emitting unit 1221, the second light-emitting unit 1222, and the third light-emitting unit 1223 may include one or more organic light-emitting layers. The first light-emitting unit 1221 is disposed on the first anode 1211. The second light-emitting unit 1222 is disposed on the second anode 1212. The third light-emitting unit 1223 is disposed on the third anode 1213. In a specific embodiment, the first light emitting unit 1221 may include a blue light-emitting unit, the second light emitting unit 1222 may include a red light-emitting unit, and the third light emitting unit 1223 may include a green light-emitting unit, but is not limited thereto.

The cathode layer 123 may include metals. A refractive index of the cathode layer 123 is less than 1. For example, the cathode layer 123 includes magnesium silver alloy. Since the cathode layer 123 includes metals, the cathode layer 123 can also reflect lights.

The first anode 1211, the first light-emitting unit 1221, and the cathode layer 123 constitute a first light-emitting device. The second anode 1212, the second light-emitting unit 1222, and the cathode layer 123 constitute a second light-emitting device. The third anode 1213, the third light-emitting unit 1223, and the cathode layer 123 constitute a third light-emitting device. Therefore, the first light-emitting device, the second light-emitting device, and the third light-emitting device share the cathode layer 123. Furthermore, the first light-emitting device, the second light-emitting device, and the third light-emitting device may further include functional layers such as a hole injection layer, a hole transport layer, an electron injection layer, and an electron transport layer.

It should be noted that for a plurality of light-emitting devices of the light-emitting device layer 12, among lights emitted by the light-emitting devices, only one part of the lights can be emitted from the display panel 100 into the air, and another part of the lights may be confined inside the light-emitting devices and cannot be used due to waveguide mode, surface plasmon mode, and absorption mode (material absorption).

The thin film encapsulation layer 15 acts as a barrier to water vapor and oxygen, so as to reduce the risk of water vapor and oxygen corroding the light-emitting device layer 12, thereby helping improve reliability of the display panel 100, and extending service life of the display panel 100. The thin film encapsulation layer 15 is disposed on a side of the light-emitting device layer 12 facing away from the substrate 11.

The thin film encapsulation layer 15 includes a first inorganic encapsulation layer 151 and an organic encapsulation layer 152. The first inorganic encapsulation layer 151 is disposed on a side of the organic encapsulation layer 152 adjacent to the light-emitting device layer 12. The thin film encapsulation layer 15 further includes a second inorganic encapsulation layer 153. The second inorganic encapsulation layer 153 is disposed on a side of the organic encapsulation layer 152 facing away from the first inorganic encapsulation layer 151.

The first inorganic encapsulation layer 151 and the second inorganic encapsulation layer 153 have better compactness, and can better block water vapor and oxygen. The organic encapsulation layer 152 has flexibility, and a thickness of the organic encapsulation layer 152 is relatively thick, so as to reduce the risk of breakage of the thin film encapsulation layer 15, and to lengthen intrusion channels of water vapor and oxygen. A combination of the organic encapsulation layer 152, the first inorganic encapsulation layer 151, and the second inorganic encapsulation layer 153 enables the thin film encapsulation layer 15 to have better barrier properties against water vapor and oxygen, and reduces the risk of the thin film encapsulation layer 15 breaking.

In some embodiments, the thickness of the organic encapsulation layer 152 is greater than or equal to 2 microns. As such, the thickness of the organic encapsulation layer 152 is thicker, so as to lengthen the intrusion channels of water vapor and oxygen, thereby improving barrier performance of the thin film encapsulation layer 15 against water vapor and oxygen. The organic encapsulation layer 152 includes organic materials such as polyimide and polyacrylate.

In some embodiments, a refractive index of the first inorganic encapsulation layer 151 and a refractive index of the second inorganic encapsulation layer 153 is greater than or equal to 1.75 and less than or equal to 2.5. As such, the refractive index of the first inorganic encapsulation layer 151 and the refractive index of the second inorganic encapsulation layer 153 is relatively great. Optionally, the refractive index of the first inorganic encapsulation layer 151 and the refractive index of the second inorganic encapsulation layer 153 is greater than or equal to 1.8 and less than or equal to 2.2.

In some embodiments, the first inorganic encapsulation layer 151 and the second inorganic encapsulation layer 153 may include at least one of silicon oxynitride and silicon nitride. Silicon oxynitride and silicon nitride have good barrier properties against water vapor and oxygen, so that the first inorganic encapsulation layer 151 and the second inorganic encapsulation layer 153 also have good barrier properties. Each of the first inorganic encapsulation layer 151 and the second inorganic encapsulation layer 153 may include a single layer or multiple layers.

In some embodiments, materials of the first inorganic encapsulation layer 151 and the second inorganic encapsulation layer 153 may be the same. For example, both the first inorganic encapsulation layer 151 and the second inorganic encapsulation layer 153 include silicon nitride, so as to improve barrier properties of the first inorganic encapsulation layer 151 and the second inorganic encapsulation layer 153 against water vapor and oxygen.

In other embodiments, materials of the first inorganic encapsulation layer 151 and the second inorganic encapsulation layer 153 may also be different. For example, the first inorganic encapsulation layer 151 includes silicon oxynitride, and the second inorganic encapsulation layer 153 includes silicon nitride. As such, the second inorganic encapsulation layer 153 farther away from the light-emitting device layer 12 has better barrier properties to water vapor and oxygen, and the first inorganic encapsulation layer 151 adjacent to the light-emitting device layer 12 has better barrier properties to water vapor and oxygen, and a value range of the refractive index of the first inorganic encapsulation layer 151 may be wider, so as to adjust the refractive index of the first inorganic encapsulation layer 151, thereby improving light extraction rate of the display panel 100 and improving a problem of large viewing angle deflection.

In some embodiments, a mass proportion of oxygen element in the first inorganic encapsulation layer 151 is less than or equal to 10%. As such, a content of oxygen element in the first inorganic encapsulation layer 151 is less, so as to improve barrier property of the first inorganic encapsulation layer 151 against water vapor and oxygen. Optionally, the mass proportion of oxygen element in the first inorganic encapsulation layer 151 is less than or equal to 8%. Optionally, the mass proportion of oxygen element in the first inorganic encapsulation layer 151 is less than or equal to 5%. Optionally, the mass proportion of oxygen element in the first inorganic encapsulation layer 151 is less than or equal to 2%.

In some embodiments, a mass proportion of the oxygen element in the second inorganic encapsulation layer 153 is less than the mass proportion of the oxygen element in the first inorganic encapsulation layer 151. As such, the second inorganic encapsulation layer 153 has better barrier properties against water vapor and oxygen.

In some embodiments, a thickness of the first inorganic encapsulation layer 151 and a thickness of the second inorganic encapsulation layer 153 are greater than or equal to 1000 nanometers and less than or equal to 5000 nanometers. As such, the thickness of the first inorganic encapsulation layer 151 and the thickness of the second inorganic encapsulation layer 153 ensured to be relatively thick, thereby improving barrier properties of the first inorganic encapsulation layer and the second inorganic encapsulation layer against water vapor and oxygen, and reducing the risk of the first inorganic encapsulation layer and the second inorganic encapsulation layer being too thick and causing breakage. Optionally, the thickness of the first inorganic encapsulation layer 151 and the thickness of the second inorganic encapsulation layer 153 are greater than or equal to 1500 nanometers and less than or equal to 4000 nanometers.

The capping layer 13 is disposed between the light-emitting device layer 12 and the thin film encapsulation layer 15. The capping layer 13 includes a first capping layer 131, a second capping layer 132, and a third capping layer 133. The second capping layer 132 is disposed between the first capping layer 131 and the third capping layer 133. The first capping layer 131 is disposed on a side of the second capping layer 132 adjacent to the light-emitting device layer 12. The third capping layer 133 is disposed on a side of the second capping layer 132 adjacent to the thin film encapsulation layer 15. A refractive index of the second capping layer 132 is greater than a refractive index of the first capping layer 131 and a refractive index of the third capping layer 133.

In some embodiments of the present application, a plurality of capping layers with different refractive indexes are disposed on the light-emitting device layer 12, and the refractive indexes of the plurality of capping layers maintain a combination of a low refractive index, a high refractive index, and a low refractive index. A combination design of the refractive indexes of the plurality of capping layers increase microcavity function outside the light-emitting device layer 12, so as to improve light extraction efficiency of lights emitted by the light-emitting device layer 12 through the capping layer 13. In addition, the combination design of the refractive indexes of the plurality of capping layers further improve light loss caused by surface plasmon mode, so that part of the lights confined inside the light-emitting device are emitted outside the display panel 100, thereby further improving light extraction efficiency of the display panel 100, and helping reduce power consumption of the display panel 100.

It should be noted that, unlike other film layers in the display panel 100, such as the thin film encapsulation layer 15, a distance between the capping layer 13 and the light-emitting device layer 12 is closer, so that the combination design of the refractive indexes of the plurality of capping layers can significantly increase microcavity function outside the light-emitting device layer 12, and effectively improve light loss of the lights emitted by the light-emitting device layer 12 due to surface plasmon mode.

It should also be noted that the capping layer 13 may also include more than three capping layers, for example, five capping layers or seven capping layers. A design principle of the capping layer 13 is to alternately provide a high refractive index capping layer and a low refractive index capping layer on one low refractive index capping layer, and each high refractive index capping layer is disposed between two adjacent low refractive index capping layers.

In some embodiments, a ratio of a refractive index of the first capping layer 131 to a refractive index of the third capping layer 133 is greater than or equal to 0.75 and less than or equal to 1.3. As such, the refractive index of the first capping layer 131 and the refractive index of the third capping layer 133 tend to be the same, materials of the first capping layer 131 and the third capping layer 133 may be the same, and manufacturing processes of the first capping layer 131 and the third capping layer 133 may be the same, thereby simplifying manufacturing processes of the capping layer 13. Alternatively, the ratio of the refractive index of the first capping layer 131 to the refractive index of the third capping layer 133 may be greater than or equal to 0.8 and less than or equal to 1.2. Alternatively, the ratio of the refractive index of the first capping layer 131 to the refractive index of the third capping layer 133 may be greater than or equal to 0.9 and less than or equal to 1.1.

In some embodiments, the refractive index of the first capping layer 131 and the refractive index of the third capping layer 133 are greater than or equal to 1.2 and less than or equal to 1.6, and the refractive index of the second capping layer 132 is greater than or equal to 1.7 and less than or equal to 2.5. As such, the refractive index of the second capping layer 132 may be greater than the refractive index of the first capping layer 131 and the refractive index of the third capping layer 133. In addition, the refractive index of the first capping layer 131 is greater than the refractive index of the cathode layer 123, thereby increasing an amount of lights emitted from the cathode layer 123 incident on the capping layer 13.

Optionally, the refractive index of the first capping layer 131 and the refractive index of the third capping layer 133 are greater than or equal to 1.3 and less than or equal to 1.5. Optionally, the refractive index of the second capping layer 132 is greater than or equal to 1.8 and less than or equal to 2.2.

In some embodiments, a thickness of the second capping layer 132 is greater than a thickness of the first capping layer 131 and a thickness of the third capping layer 133. As such, the thickness of the second capping layer 132 is thicker, so as to better increase microcavity function outside the light-emitting device layer 12, thereby further improving light extraction efficiency of the lights emitted by the light-emitting device layer 12 through the capping layer 13.

In some embodiments, the thickness of the second capping layer 132 is greater than a sum of the thicknesses of the first capping layer 131 and the second capping layer 132. As such, the thickness of the second capping layer 132 is thicker, so as to better increase microcavity function outside the light-emitting device layer 12, thereby further improving light extraction efficiency of the lights emitted by the light-emitting device layer 12 through the plurality of capping layers.

In some embodiments, a ratio of the thickness of the first capping layer 131 to the thickness of the third capping layer 133 may be greater than or equal to 0.8 and less than or equal to 1.2. As such, the thickness of the first capping layer 131 and the thickness of the third capping layer 133 may be the same, and the manufacturing processes of the first capping layer 131 and the third capping layer 133 may be the same, thereby simplifying the manufacturing process of the capping layer 13.

In some embodiments, the thickness of the first capping layer 131 and the thickness of the third capping layer 133 are greater than or equal to 100 angstroms and less than or equal to 500 angstroms, and the thickness of the second capping layer 132 is greater than or equal to 500 angstroms and less than or equal to 700 angstroms. As such, the thickness of the second capping layer 132 is greater than the thickness of the first capping layer 131 and the thickness of the third capping layer 133. Optionally, the thickness of the first capping layer 131 and the thickness of the third capping layer 133 are greater than or equal to 150 angstroms and less than or equal to 300 angstroms, and the thickness of the second capping layer 132 is greater than or equal to 550 angstroms and less than or equal to 650 angstroms.

In some embodiments, the capping layer 13 may include organic materials, but is not limited thereto. The capping layer 13 may also include inorganic materials.

In some embodiments, a material of the second capping layer 132 is different from materials of the first capping layer 131 and the third capping layer 133. As such, the refractive index of the second capping layer 132 is greater than the refractive index of the first capping layer 131 and the refractive index of the third capping layer 133.

In some embodiments, the first capping layer 131 and the third capping layer 133 may be made of the same material. As such, the manufacturing processes of the first capping layer 131 and the third capping layer 133 may be the same, thereby simplifying the manufacturing process of the capping layer 13. In other embodiments, the materials of the first capping layer 131 and the second capping layer 132 may be different.

In some embodiments, in a case that the capping layer 13 includes organic materials, the capping layer with a low refractive index, for example, the first capping layer 131 and the third capping layer 133, may include aromatic compounds containing fluorine element or trifluoromethyl. In some embodiments, the capping layer with a high refractive index, for example, the second capping layer 132, may include a conjugated structure of benzoxazole.

In some embodiments, in the case that the first capping layer 131 to the third capping layer 133 include organic materials, the first capping layer 131 to the third capping layer 133 of the capping layer 13 may be formed using an evaporation process, but are not limited to this.

In some embodiments, the display panel 100 may further include a light-transmitting protective layer 14 disposed between the third capping layer 133 and the thin film encapsulation layer 15. A ratio of a refractive index of the light-transmitting protective layer 14 to the refractive index of the third capping layer 133 is greater than or equal to 0.75 and less than or equal to 1.3. As such, the light-transmitting protective layer 14 protect the capping layer 13 during subsequent process of forming the thin film encapsulation layer 15. In addition, the refractive index of the light-transmitting protective layer 14 and the refractive index of the third capping layer 133 tend to be the same, so that more lights emitted from the capping layer 13 can be incident into the light-transmitting protective layer 14. That is, the refractive index of the third capping layer 133 matches the refractive index of the light-transmitting protective layer 14, so as to further improve transmittance of the lights emitted by the light-emitting device layer 12 through the capping layer 13 and the light-transmitting protective layer 14, thereby improving light extraction efficiency of the lights emitted by the display panel 100.

Optionally, the ratio of the refractive index of the light-transmitting protective layer 14 to the refractive index of the third capping layer 133 is greater than or equal to 0.8 and less than or equal to 1.2. Optionally, the ratio of the refractive index of the light-transmitting protective layer 14 to the refractive index of the third capping layer 133 is greater than or equal to 0.9 and less than or equal to 1.1.

In some embodiments, the refractive index of the light-transmitting protective layer is greater than or equal to 1.2 and less than or equal to 1.6. As such, the refractive index of the third capping layer 133 and the refractive index of the light-transmitting protective layer 14 tend to be the same.

It should be noted that in related technologies, in a case that the capping layer has only one film layer, an inorganic encapsulation layer of the thin film encapsulation layer is generally used to improve problem of large viewing angle deviation of the display panel. In some embodiments of the present application, a plurality of capping layers with low refractive index in the capping layer 13 and the light-transmitting protective layer 14 are both low refractive index film layers, these low refractive index film layers are adjusted to improve light extraction efficiency of the display panel and to improve the problem of large viewing angle deviation of the display panel 100. Therefore, the design of the capping layers 13 with a plurality of layers, and the design of the light-transmitting protective layer is more conducive to improving light extraction efficiency of the display panel 100 and improving the problem of large viewing angle deviation.

In some embodiments, a sum of the thickness of the third capping layer 133 and a thickness of the light-transmitting protective layer 14 is greater than the thickness of the first capping layer 131. As such, the thickness of the first capping layer 131 is less, thereby helping improve light extraction efficiency of the lights emitted by the light-emitting device layer 12 through the first capping layer 131.

In some embodiments, the refractive index of the first inorganic encapsulation layer 151 is greater than the refractive index of the light-transmitting protective layer 14. As such, microcavity function outside the light-emitting device layer 12 is further enhanced, and light extraction efficiency of the lights emitted by the light-emitting device layer 12 through the capping layer 13, the light-transmitting protective layer 14 and the thin film encapsulation layer 15 is improved.

In some embodiments, the light-transmitting protective layer 14 includes an alkali metal element and an halogen element. As such, in the case that the refractive indexes of the light-transmitting protective layer 14 and the third capping layer 133 tend be the same, manufacturing temperature of the light-transmitting protective layer 14 may also be reduced, and difficulty of the manufacturing process of the light-transmitting protective layer 14 may be reduced. For example, the light-transmitting protective layer 14 may include lithium fluoride.

In some embodiments, the thickness of the first inorganic encapsulation layer 151 is greater than a sum of a thickness of the capping layer 13 and the thickness of the light-transmitting protective layer 14. As such, the thickness of the first inorganic encapsulation layer 151 is thicker, so that the first inorganic encapsulation layer 151 which is closer to the light-emitting device layer 12 has good barrier properties against water vapor and oxygen.

In some embodiments, in a case that the first light-emitting unit 1221 of the light-emitting device layer 12 includes a blue light-emitting unit, a half-peak width of a blue light emission spectrum of the blue light-emitting unit is greater than or equal to 25 nanometers and less than or equal to 34 nanometers. As such, the half-peak width of the blue light emission spectrum of the display panel is narrower, microcavity effect of the light-emitting device that emits blue light is enhanced, so as to improve light extraction efficiency of blue light, thereby helping reduce power consumption required to emit blue light, and reducing overall cost of power consumption of the display panel 100. Optionally, the half-peak width of the blue light emission spectrum of the blue light-emitting unit is greater than or equal to 28 nanometers and less than or equal to 32 nanometers.

As shown in FIG. 1, the display panel 100 further includes a driving circuit layer 161. The driving circuit layer 16 is disposed between the light-emitting device layer 12 and the substrate 11. The driving circuit layer 161 includes a pixel driving circuit. The pixel driving circuit is connected to the light-emitting device to drive the light-emitting device to emit lights. The pixel driving circuit may include a thin film transistor and a capacitor.

As shown in FIG. 1, the display panel 100 further includes a pixel definition layer 162. The pixel definition layer 162 is disposed on a side of the driving circuit layer 161 facing away from the substrate 11. The pixel definition layer 162 is provided with a plurality of pixel openings 162a to define light-emitting regions of the light emitting devices. The anode layer 121 is disposed on the driving circuit layer 161. The pixel definition layer 162 is disposed on the anode layer 121. The plurality of pixel openings 162a expose the first anode 1211, the second anode 1212, and the third anode 1213. The first light-emitting unit 1221, the second light-emitting unit 1222, and the third light-emitting unit 1223 are disposed in the plurality of pixel openings 162a.

As shown in FIG. 2, in some embodiments of the present application, the design of the capping layer 13, the light-transmitting protective layer 14, and the thin film encapsulation layer 15 match each other, thereby increasing microcavity function outside the light-emitting device layer 12. For example, for the lights emitted from the cathode layer 123, a first part of the lights, namely a first light L1, are emitted into air outside the display panel 100. A second part of the lights are reflected at an interface between the second capping layer 132 with high refractive index and the third capping layer 133 with low refractive index, one part of reflected lights are incident on the cathode layer 123 and are reflected by the cathode layer 123, and is further emitted into air as a second light L2, and another part of the reflected lights are incident on the anode layer 121 and are emitted into air as a third light L3 after being reflected by the anode layer 121. A third part of the lights are reflected at an interface between the first inorganic encapsulation layer 151 and the organic encapsulation layer 152, a part of reflected lights are incident on the cathode layer 123 and are emitted as a fourth light L4 after being reflected by the cathode layer 123. Interferences of a plurality of beams can be formed between the first light L1, the second light L2, the third light L3, and the fourth light L4, thereby enhancing light extraction efficiency of the lights emitted by the light-emitting device layer 12.

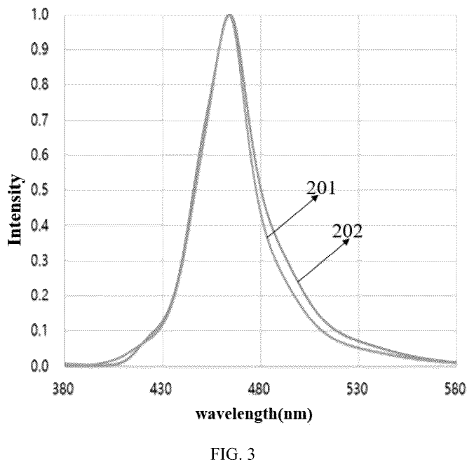

As shown in FIG. 3, FIG. 3 shows a blue light emission spectrum of a blue light-emitting unit of the display panel according to some embodiments of the present application and a blue light emission spectrum of a blue-light emitting unit of a display panel of a comparative example. A structure of the display panel 100 according to some embodiments of the present application is shown in FIG. 1, the difference between the display panel of the comparative example and the display panel 100 shown in FIG. 1 is that the capping layer of the display panel of the comparative example only includes the second capping layer 132 and does not include the first capping layer 131 and the third capping layer 133. In addition, a line 201 in FIG. 3 represents the blue light emission spectrum of the blue light-emitting unit of the display panel 100 of some embodiments of the present application, and a line 202 represents the blue light emission spectrum of the blue light-emitting unit of the display panel of the comparative example.

It can be seen from FIG. 3 that the half-peak width of the blue light emission spectrum of the blue light-emitting unit is 31 nanometers for the display panel 100 of some embodiments of the present application, and the half-peak width of the blue light emission spectrum of the blue light emitting unit is 35 nanometers for the blue light emission spectrum of the blue light-emitting unit of the display panel of the comparative example. Therefore, the half-peak width of the blue emission spectrum of the blue light-emitting unit of the display panel 100 of some embodiments of the present application is narrower than the half-peak width of the blue emission spectrum of the blue light-emitting unit of the display panel of the comparative example. The combination of the plurality of capping layers with different refractive indexes in the display panel of some embodiments of the present application enhances microcavity effect, thereby increasing light extraction efficiency of blue light.

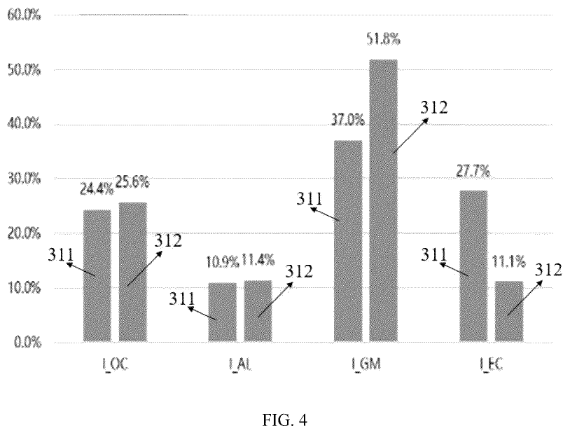

As shown in FIG. 4, FIG. 4 shows proportion of lights emitted by the display panel of some embodiments of the present application in four modes and proportion of lights emitted by the display panel of the comparative example in the four modes. The structure of the display panel 100 according to some embodiments of the present application is shown in FIG. 1. The difference between the display panel of the comparative example and the display panel shown in FIG. 1 is that the capping layer of the display panel of the comparative example only includes the second capping layer and does not include the first capping layer and the third capping layer. The four modes include I_GM, I_OC, I_AL and I_EC. Among them, I_GM is waveguide mode, I_OC is air mode, I_AL is absorption mode, and I_EC is surface plasmon mode. Air mode corresponds to a proportion of lights emitted by the display panel 100 incident into air. Reference numeral 312 in FIG. 4 marks a test result of the display panels of some embodiments of the present application, and reference numeral 311 marks a test result of the display panel of the comparative example.

It can be seen from FIG. 4 that light extraction efficiency of the lights emitted by the display panel of the comparative example is 24.4%, and light extraction efficiency of lights emitted by the display panel 100 of some embodiments of the present application is 25.6%. Light extraction efficiency of the display panel 100 in some embodiments of the present application is improved, thereby helping reduce power consumption of the display panel 100. In addition, compared with the comparative example, loss of lights emitted by the display panel 100 of some embodiments of the present application due to surface plasmon mode I_EC is reduced by 16.6%. Therefore, the loss caused by surface plasmon mode is significantly improved in the display panel 100 of some embodiments of the present application. The reason is related to a fact that the capping layer 131 with low refractive index in the capping layer 13 can change a wave vector at the cathode layer 123.

Based on the same inventive concept, the present application further provides a display device. The display device includes the above-mentioned display panel 100. The display device may be applied to display devices such as smartphones, smart watches, desktop computers, notebook computers, and televisions.

To sum up, for the display panel and display device, a plurality of capping layers are disposed on the light-emitting device layer, and refractive indexes of the plurality of capping layers maintain a combination of a low refractive index, a high refractive index, and a low refractive index. A combination design of the refractive indexes of the plurality of capping layers increase microcavity function outside the light-emitting device layer, so as to improve light extraction efficiency of lights emitted by the light-emitting device layer through the capping layer. In addition, the combination design of the refractive indexes of the plurality of capping layers further improve light loss caused by surface plasmon mode, so that part of the lights confined inside light-emitting devices are emitted outside the display panel, thereby further improving light extraction efficiency of the display panel, and helping reduce power consumption of the display panel.

The descriptions of the above-mentioned embodiments are only used to help understand the technical solutions and core ideas of the present application. Those of ordinary skill in the art should understand that they can still modify the technical solutions described in the foregoing embodiments, or equivalently replace some of the technical features; and these modifications or replacements do not cause the essence of the corresponding technical solutions to deviate from the scope of the technical solutions of the embodiments of the present application.

What is claimed is:

1. A display panel, comprising:
a substrate;
a light-emitting device layer disposed on a side of the substrate;
a thin film encapsulation layer disposed on a side of the light-emitting device layer facing away from the substrate; and
a capping layer disposed between the light-emitting device layer and the thin film encapsulation layer, wherein the capping layer comprises a first capping layer, a second capping layer, and a third capping layer, the second capping layer is disposed between the first capping layer and the third capping layer, the first capping layer is disposed on a side of the second capping layer adjacent to the light-emitting device layer, the third capping layer is disposed on a side of the second capping layer adjacent to the thin film encapsulation layer, a refractive index of the second capping layer is greater than a refractive index of the first capping layer and a refractive index of the third capping layer.

2. The display panel according to claim 1, wherein a ratio of the refractive index of the first capping layer to the refractive index of the third capping layer is greater than or equal to 0.75 and less than or equal to 1.3.

3. The display panel according to claim 1, wherein the refractive index of the first capping layer and the refractive index of the third capping layer are greater than or equal to 1.2 and less than or equal to 1.6, and the refractive index of the second capping layer is greater than or equal to 1.7 and less than or equal to 2.5.

4. The display panel according to claim 1, wherein a thickness of the second capping layer is greater than a thickness of the first capping layer and a thickness of the third capping layer.

5. The display panel according to claim 1, further comprising:
a light-transmitting protective layer disposed between the third capping layer and the thin film encapsulation layer, and a ratio of a refractive index of the light-transmitting protective layer to the refractive index of the third capping layer is greater than or equal to 0.75 and less than or equal to 1.3.

6. The display panel according to claim 5, wherein a sum of a thickness of the third capping layer and a thickness of the light-transmitting protective layer is greater than a thickness of the first capping layer.

7. The display panel according to claim 5, wherein the light-transmitting protective layer comprises an alkali metal element and a halogen element.

8. The display panel according to claim 5, wherein the thin film encapsulation layer comprises:
an organic encapsulation layer; and
an inorganic encapsulation layer disposed between the organic encapsulation layer and the capping layer, wherein a refractive index of the inorganic encapsulation layer is greater than the refractive index of the light-transmitting protective layer.

9. The display panel according to claim 8, wherein the refractive index of the inorganic encapsulation layer is greater than or equal to 1.75 and less than or equal to 2.5, and the refractive index of the light-transmitting protective layer is greater than or equal to 1.2 and less than or equal to 1.6.

10. The display panel according to claim 8, wherein a thickness of the inorganic encapsulation layer is greater than a sum of a thickness of the capping layer and a thickness of the light-transmitting protective layer.

11. The display panel according to claim 8, wherein a mass proportion of oxygen element in the inorganic encapsulation layer is less than or equal to 10%.

12. The display panel according to claim 1, wherein the light-emitting device layer comprises a blue light-emitting unit, and a half-peak width of a blue light emission spectrum of the blue light-emitting unit is greater than or equal to 25 nanometers and less than or equal to 34 nanometers.

13. A display device, comprising a display panel, the display panel comprising:
a substrate;
a light-emitting device layer disposed on a side of the substrate;
a thin film encapsulation layer disposed on a side of the light-emitting device layer facing away from the substrate; and
a capping layer disposed between the light-emitting device layer and the thin film encapsulation layer, wherein the capping layer comprises a first capping layer, a second capping layer, and a third capping layer, the second capping layer is disposed between the first capping layer and the third capping layer, the first capping layer is disposed on a side of the second capping layer adjacent to the light-emitting device layer, the third capping layer is disposed on a side of the second capping layer adjacent to the thin film encapsulation layer, a refractive index of the second capping layer is greater than a refractive index of the first capping layer and a refractive index of the third capping layer.

14. The display device according to claim 13, wherein a ratio of the refractive index of the first capping layer to the refractive index of the third capping layer is greater than or equal to 0.75 and less than or equal to 1.3.

15. The display device according to claim 13, wherein a thickness of the second capping layer is greater than a thickness of the first capping layer and a thickness of the third capping layer.

16. The display device according to claim 13, the display panel further comprising:
a light-transmitting protective layer disposed between the third capping layer and the thin film encapsulation layer, and a ratio of a refractive index of the light-transmitting protective layer to the refractive index of the third capping layer is greater than or equal to 0.75 and less than or equal to 1.3.

17. The display device according to claim 16, wherein a sum of a thickness of the third capping layer and a thickness of the light-transmitting protective layer is greater than a thickness of the first capping layer.

18. The display device according to claim 16, wherein the light-transmitting protective layer comprises an alkali metal element and a halogen element.

19. The display device according to claim 16, wherein the thin film encapsulation layer comprises:
an organic encapsulation layer; and
an inorganic encapsulation layer disposed between the organic encapsulation layer and the capping layer, wherein a refractive index of the inorganic encapsulation layer is greater than the refractive index of the light-transmitting protective layer.

20. The display device according to claim 19, wherein a thickness of the inorganic encapsulation layer is greater than a sum of a thickness of the capping layer and a thickness of the light-transmitting protective layer.
